(19) United States
(12) Patent Application Publication
(10) Pub. No.: US 2026/0305130 A1
(43) Pub. Date: Oct. 1, 2026

(54) DISPLAY MODULE AND DISPLAY APPARATUS

(71) Applicants: Beijing BOE Technology Development Co., Ltd., Beijing (CN); BOE TECHNOLOGY GROUP CO., LTD., Beijing (CN)

(72) Inventors: Boyang Shi, Beijing (CN); Hong Zhu, Beijing (CN); Xinqi Lin, Beijing (CN); Junhuan Liu, Beijing (CN)

(73) Assignees: Beijing BOE Technology Development Co., Ltd., Beijing (CN); BOE TECHNOLOGY GROUP CO., LTD., Beijing (CN)

(21) Appl. No.: 19/479,515

(22) PCT Filed: Jan. 6, 2025
(86) PCT No.: PCT/CN2025/070767

§ 371 Date: Oct. 28, 2025

(30) Foreign Application Priority Data
Jan. 8, 2024 (CN) 202410026732.1

(51) Int. Cl. H10K 59/80; H10K 102/00

(52) U.S. Cl. CPC H10K 59/8722; H10K 59/873; H10K 2102/311; H10K 2102/351

(57) ABSTRACT

Provided is a display module, including: a film layer group, a supporting member and a rotating shaft. The film layer group includes a flexible region and a non-flexible region connecting the flexible region; the supporting member includes a supporting portion and a sliding portion connecting the supporting portion, the supporting portion is at least arranged in the flexible region, and the sliding portion is slidably connected with a housing; and the flexible region is wound around the rotating shaft such that a part of the flexible region overlaps with the non-flexible region. The supporting member is arranged between the film layer group and the rotating shaft.

### CROSS-REFERENCE TO RELATED APPLICATION(S)

This application is a Section 371 National Stage Application of International Application NO. PCT/CN2025/070767, filed on Jan. 6, 2025, which claims priority to Chinese Patent Application No. 202410026732.1, filed on Jan. 8, 2024, the whole contents of which are incorporated herein by reference in their entireties.

### TECHNICAL FIELD

The present disclosure relates to the field of display technologies, and in particular to a display module and a display apparatus.

### BACKGROUND

In the related art, a flexible portion of a foldable display screen is wound around a rotating shaft, the foldable display may rotate relative to the rotating shaft to achieve various different display areas. However, during a rotation process, the flexible portion contacts the rotating shaft, stress-strain may occur in a wound portion, resulting in deformation of the flexible portion.

### SUMMARY

The present disclosure is intended to at least solve the technical problem of a service life of a display module to a certain extent. To this end, the present disclosure provides a display module and a display apparatus.

In a first aspect, a display module is provided by the embodiments of the present disclosure, including: a film layer group including a flexible region and a non-flexible region connected with the flexible region; a supporting member including a supporting portion and a sliding portion connected with the supporting portion, the supporting portion is at least arranged in the flexible region, and the sliding portion is slidably connected with a housing; and a rotating shaft, the flexible region is wound around the rotating shaft, such that at least a part of the flexible region overlaps with the non-flexible region.

In some embodiments, the supporting member is arranged between the film layer group and the rotating shaft.

In a second aspect, a display apparatus is further provided by the embodiments of the present disclosure, including the display module provided in the first aspect.

### BRIEF DESCRIPTION OF THE DRAWINGS

In order to more clearly illustrate the technical solutions in the embodiments of the present disclosure, a brief introduction will be given below to the drawings required for use in the descriptions of the embodiments. Obviously, the drawings described below are some embodiments of the present disclosure, and other drawings may be obtained by those of ordinary skill in the art based on these drawings without any creative work.

FIG. 1 shows a schematic structural diagram of a display module provided according to one or more embodiments of the present disclosure.

FIG. 2 shows an exploded diagram of a supporting member provided according to one of the embodiments of the present disclosure.

FIG. 3 shows a schematic structural diagram of a supporting portion of a supporting member provided according to one of the embodiments of the present disclosure.

FIG. 4 shows a film layer diagram of a display module provided according to the embodiments of the present disclosure.

FIG. 5 shows a schematic structural diagram of a supporting member provided according to some other embodiments of the present disclosure.

FIG. 6 shows an exploded diagram of point A in FIG. 5.

FIG. 7 shows an exploded diagram of a supporting member in FIG. 5.

FIG. 8 is a schematic structural diagram showing a display module having two supporting members provided according to the embodiments of the present disclosure.

FIG. 9 shows a schematic structural diagram, in which a step difference of a second packaging layer of a display module provided according to the embodiments of the present disclosure faces upward.

FIG. 10 shows a schematic structural diagram, in which a step difference of a second packaging layer of a display module provided according to the embodiments of the present disclosure faces upward.

FIG. 11 shows a film layer diagram of a display module provided according to some other embodiments of the present disclosure.

FIG. 12 shows a schematic structural diagram of a display module having two rotating shafts provided according to the embodiments of the present disclosure.

FIG. 13 shows a schematic structural diagram of a display module having three rotating shafts provided according to the embodiments of the present disclosure.

### REFERENCE SIGNS

100—display module, 110—film layer group, 112a—flexible region, 112b—non-flexible region, 113—first packaging layer, 114—first connecting layer, 115—second packaging layer, 115a—first section, 115b—second section, 115c—coating, 116—second connecting layer, 117—polarizer, 118—display layer, 119—back film layer.
120—supporting member, 121—supporting portion, 121a—supporting strip, 121b—connecting portion 122—sliding portion, 123—supporting plate, 124—first adhesive layer, 125—fixing plate, 126—second adhesive layer, 126a—adhesive strip, W1—first width, S1—first distance, W2—second width, S2—second distance.
130—rotating shaft, 131—first rotating shaft, 132—second rotating shaft, 133—third rotating shaft.

### DETAILED DESCRIPTION OF EMBODIMENTS

The technical solutions in the embodiments of the present disclosure will be clearly and completely described below in conjunction with the drawings in the embodiments of the present disclosure. Obviously, the described embodiments are only a part of the embodiments of the present disclosure, not all the embodiments. Based on the embodiments of the present disclosure, all other embodiments obtained by those of ordinary skill in the art without any creative work shall fall within the scope of protection of the present disclosure.

It should be noted that all directional indications in the embodiments of the present disclosure are only used to explain relative position relationships and movement situations of various components in a certain specific posture. If the specific posture changes, the directional indications will also change accordingly. In the present disclosure, unless otherwise clearly specified or limited, the terms “connected”, “fixed”, etc. should be understood in a broader sense. For example, “fixed” may be a fixed connection, a detachable connection, or an integral connection; “connected” may be a mechanical connection or an electrical connection, a direct connection or an indirect connection through an intermediate medium, an internal connection of two elements or an interaction relationship between two elements, unless otherwise clearly specified or limited. For those skilled in the art, the specific meanings of the above terms in the present disclosure may be understood according to specific situations.

In addition, descriptions such as “first”, “second”, etc. in the present disclosure are only used for descriptive purposes and may not be understood as indicating or implying their relative importance or implicitly indicating the number of the indicated technical features. Therefore, features defined as “first” and “second” may explicitly or implicitly include at least one of said features. In addition, the technical solutions of various embodiments may be combined with each another on a basis that such combination may be implemented by those of ordinary skill in the art. When a combination of technical solutions is mutually contradictory or may not be implemented, it should be deemed that such combination of technical solutions does not exist and does not fall within the scope of protection of the present disclosure.

OLED (Organic light emitting diode) display devices have gradually become the first choice for display screens. An OLED has many advantages such as self-luminescence, short response time, high clarity and contrast, and may also has certain flexibility and adaptability. Regarding these characteristics of OLED screens, the display industry has developed folding products in different forms. A folding form has limitations while bringing new experiences to the consumers. For example, a display region may only be switched between two display areas, and there are crease problems caused by continuous folding of a fixed position.

In the related art, a flexible portion of a foldable display screen is wound around a rotating shaft, the foldable display may rotate relative to the rotating shaft to achieve various different display areas. During a rotation process, the flexible portion contacts the rotating shaft, and stress-strain will occur in the wound portion, resulting in deformation of the flexible portion. The display module and the display apparatus provided by the embodiments of the present disclosure may relieve the above problem. The display module and the display apparatus provided by the embodiments of the present disclosure may reduce the stress-strain of a film layer group while ensuring mechanical properties of each portion.

The present disclosure will be described below with reference to the accompanying drawings and specific embodiments.

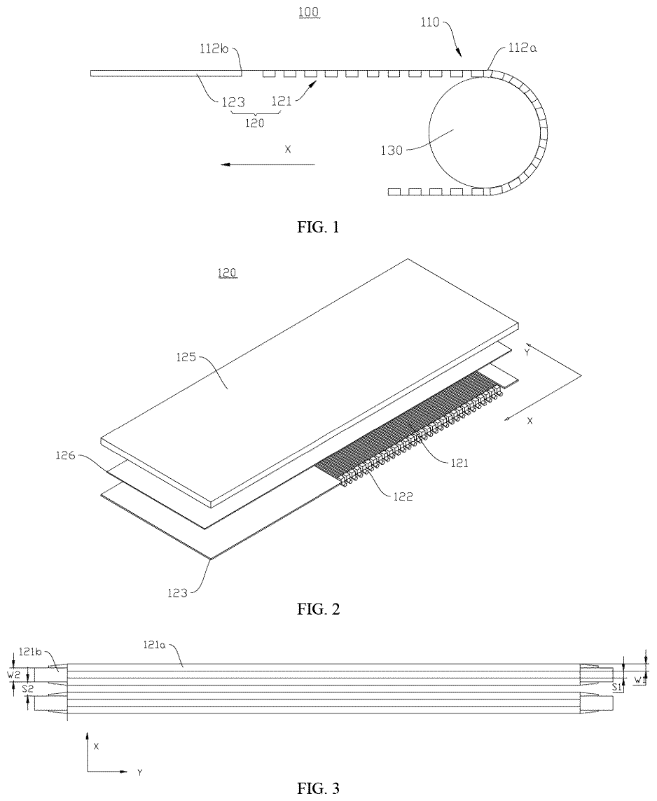

Referring to FIG. 1 and FIG. 2, the embodiments of the present disclosure provide a display module 100. The display module 100 provided by the embodiments of the present disclosure may reduce an occurrence of breakage of a film layer group 110 during a sliding process, thereby increasing a service life of the entire display module 100.

In the embodiments of the present disclosure, the display module 100 includes: a film layer group 110, a supporting member 120 and a rotating shaft 130. The film layer group 110 includes a flexible region 112a and a non-flexible region 112b connected with the flexible region 112a. The supporting member 120 includes a supporting portion 121 and a sliding portion 122 connected with the supporting portion 121. The supporting portion 121 is at least arranged in the flexible region 112a, and the sliding portion 122 is slidably connected with a housing. The flexible region 112a is wound around the rotating shaft 130, so that at least a part of the flexible region 112a may be overlapped with the non-flexible region 112b. In some embodiments, the supporting member 120 is arranged between the film layer group 110 and the rotating shaft 130.

In some embodiments, the film layer group 110 includes key structures of the display module 100 such as a display layer 118 and a packaging layer. A non-display surface of the film layer group 110 is wound around the rotating shaft 130, so that the film layer group 110 may slide relative to the rotating shaft 130, thereby enabling the display module 100 with various different display areas.

The supporting portion 121 is at least arranged in the flexible region 112a, which means that the supporting portion 121 may be arranged only in the flexible region 112a, or may be arranged in the flexible region 112a and the non-flexible region 112b simultaneously, as long as the flexible region 112a is provided with the supporting portion 121. The supporting member 120 is arranged between the film layer group 110 and the rotating shaft 130, and the non-display surface of the film layer group 110 contacts the rotating shaft 130. Therefore, the supporting member 120 is arranged on the non-display surface of the film layer group 110, and the supporting member 120 is arranged between the rotating shaft 130 and the film layer group 110, so that the non-display surface of the film layer group 110 does not directly contact the rotating shaft 130.

The sliding portion 122 is slidably connected with the housing, that is, the supporting portion 121 may be slidably connected with the housing through the sliding portion 122. The supporting portion 121 is arranged on the non-display surface of the flexible region 112a, during the sliding process of the entire film layer group 110, the supporting portion 121 and the sliding portion 122 may cooperate to provide a certain support for the film layer group 110, thereby reducing a stress generated during contact of the film layer group 110 with the rotating shaft 130, reducing a stress-strain on the film layer group 110, reducing the occurrence of breakage of the film layer group 110 during the sliding process, and thus improving the service life of the entire display module 100.

In the embodiments of the present disclosure, the film layer group 110 is roughly rectangular. For the convenience of description, a sliding direction of the film layer group 110 is defined as a length direction (such as the X-axis direction shown in FIG. 1 and FIG. 2), and a direction of the other side is defined as a width direction (such as the Y-axis direction shown in FIG. 1 and FIG. 2).

In some embodiments, a slide rail may be provided on the housing, and the sliding portion 122 may be assembled in the slide rail, so that during an unfolding or retracting process of the film layer group 110, the sliding portion 122 may slide relative to the slide rail, thereby reducing a friction with the housing and facilitating unfolding or retracting of the film layer group 110.

Referring to FIG. 3, in some embodiments, the supporting portion 121 includes a plurality of supporting strips 121a and a plurality of connecting portions 121b. In the sliding direction of the film layer group 110, the plurality of supporting strips 121a are spaced apart in the flexible region 112a, and the connecting portion 121b connects two adjacent supporting strips 121a. A plurality of sliding portions 122 are provided and are mounted on the connecting portions 121b.

In some embodiments, the supporting strip 121a is in a shape of a long strip, and a plurality of supporting strips 121a are sequentially spaced apart along the sliding direction of the film layer group 110. That is, the plurality of supporting strips 121a are sequentially spaced apart along the length direction of the film layer group 110, and an extension direction of the supporting strip 121a is the same as the width direction of the film layer group 110. That is, the supporting strip 121a spans across the film layer group 110, and a length direction of the supporting strip 121a is the width direction of the film layer group 110, while a width direction of the supporting strip 121a is the sliding direction of the film layer group 110, i.e., the length direction of the film layer group 110.

Two ends of the supporting strip 121a are provided with the connecting portions 121b, that is, the two ends of the supporting strip 121a are provided with the sliding portions 122, and the two ends of the supporting strip 121a are slidably connected with the housing via the sliding portions 122. That is, the supporting portions 121 may support the film layer group 110 from two sides in the width direction of the film layer group 110, thereby improving a supporting force on the film layer group 110, reducing the stress on the film layer group 110 during contact with the rotating shaft 130, reducing the risk of breakage of the film layer group 110, and thus improving the service life of the film layer group 110.

The plurality of supporting strips 121a are spaced apart, which may not only provide a sufficient support force for the film layer group 110, but also provide a certain pressing tactility feeling when the user operates the entire display module 100, thereby improving the user experience.

The connecting portion 121b connects two adjacent supporting strips 121a in at least two different connection manners. Taking four consecutive adjacent supporting strips 121a as an example, which are respectively a first supporting strip 121a, a second supporting strip 121a, a third supporting strip 121a and a fourth supporting strip 121a. In some embodiments, a left end of the first supporting strip 121a is connected with a left end of the second supporting strip 121a, a right end of the first supporting strip 121a is connected with a right end of the second supporting strip 121a, a left end of the third supporting strip 121a is connected with a left end of the fourth supporting strip 121a, and a right end of the third supporting strip 121a is connected with a right end of the fourth supporting strip 121a. That is, two supporting strips 121a may form a whole.

In addition, additionally, the left end of the first supporting strip 121a is connected with the left end of the second supporting strip 121a, the right end of the second supporting strip 121a is connected with the right end of the third supporting strip 121a, the left end of the third supporting strip 121a is connected with the left end of the fourth supporting strip 121a, and so on, so that the entire supporting portion 121 is roughly in the form of a plurality of continuous Z shapes.

In some embodiments, in the sliding direction of the film layer group 110, a width of the supporting strip 121a is a first width W1, a width of the connecting portion 121b is a second width W2, and the second width W2 is greater than the first width W1.

In some embodiments, the supporting strip 121a spans across the film layer group 110 and is mounted in the flexible region 112a, and is wound around the rotating shaft 130 along with the flexible region 112a. In order to take into account both the supporting force of the supporting strip 121a on the film layer group 110 and flexibility of the flexible region 112a, the width of the supporting strip 121a in the length direction of the film layer group 110 may be set to be relatively small. The connecting portion 121b is connected with the sliding portion 122, and the sliding portion 122 needs to be slidably connected with the housing. If the width of the connecting portion 121b is set to be relatively small, it will be difficult to mount the sliding portion 122. Therefore, the connecting portion 121b and the supporting strip 121a may be set to have different widths to meet respective needs.

Therefore, the second width W2 may be greater than the first width W1, and the width of the supporting strip 121a is relatively small, so that the supporting strip 121a may support the film layer group 110 while maintaining a certain degree of flexibility. The width of the connecting portion 121b is set to be relatively large, which may facilitate assembly of the sliding portion 122.

In some embodiments, in the sliding direction of the film layer group 110, a distance between two adjacent supporting strips 121a is a first distance S1, a distance between two adjacent connecting portions 121b is a second distance S2, and the second distance S2 is greater than the first distance S1.

The supporting strip 121a spans across the film layer group 110 and is mounted in the flexible region 112a, and is wound around the rotating shaft 130 along with the flexible region 112a. A width of the supporting member 120 should not be set too large. In the case that the width of the supporting strip 121a is relatively small, in order to improve the supporting force of the entire supporting member 120 on the film layer group 110, the number of supporting strips 121a needs to be set to be relatively large, that is, a distance between two adjacent supporting strips 121a needs to be set to be relatively small, that is, the first distance S1 needs to be set to be relatively small, so as to ensure the supporting force of the entire supporting member 120 on the film layer group 110.

The connecting portion 121b is connected with the sliding portion 122, and the sliding portion 122 needs to slide relative to the housing. A certain distance needs to be maintained between two adjacent sliding portions 122 to avoid interference between two adjacent sliding portions 122 as much as possible. Therefore, the distance between two adjacent sliding portions 122 needs to be set to be relatively large. The sliding portion 122 is mounted on the connecting portion 121b, therefore the distance between two adjacent connecting portions 121b needs to be set to be relatively large, that is, the second distance S2 needs to be relatively large.

Correspondingly, the second distance S2 may be greater than the first distance S1. The first distance S1 between two adjacent supporting strips 121a is relatively small, which may increase the supporting force on the film layer group 110. The second distance S2 between two adjacent connecting portions 121b is relatively large, which may provide a certain sliding activity to the sliding portion 122 and avoid interference as much as possible.

In some embodiments, the first distance S1 is greater than 0.5 mm and less than 1 mm. The first width W1 is greater than 0.5 mm and less than 1 mm. The supporting strip 121a is mainly used to support the film layer group 110. The first distance S1 and the first width W1 may not be set too large. If the first distance S1 and the first width W1 are set too large. the film layer group 110 will be deformed due to excessive stress. The first distance S1 is greater than 0.5 mm and less than 1 mm, and the first width W1 is greater than 0.5 mm and less than 1 mm, which may reduce the strain of the film layer group 110.

In some embodiments, the first distance S1 may be 0.5 mm, 0.6 mm, 0.7 mm, 0.8 mm, 0.9 mm, or 1 mm. The first width W1 may be 0.5 mm, 0.6 mm, 0.7 mm, 0.8 mm, 0.9 mm, or 1 mm.

In some embodiments, in the sliding direction of the film layer group 110, the width of the connecting portion 121b is the second width W2, the distance between two adjacent connecting portions 121b is the second distance S2, and a sum of the second width W2 and the second distance S2 is greater than 2 mm. Since the first width W1 and the first distance S1 are both less than 1 mm, the connecting portion 121b needs to connect two adjacent supporting strips 121a and provide a relatively large sliding space for the sliding portion 122. The sum of the second width W2 and the second distance S2 may be greater than 2 mm.

In some embodiments, the sum of the second width W2 and the second distance S2 may be 2.1 mm, 2.2 mm, 2.3 mm, 2.4 mm, 2.5 mm, or 2.6 mm.

In some embodiments, the supporting strips 121a may be arranged only in the flexible region 112a, and the supporting member 120 further includes a supporting plate 123 which may be arranged in the non-flexible region 112b.

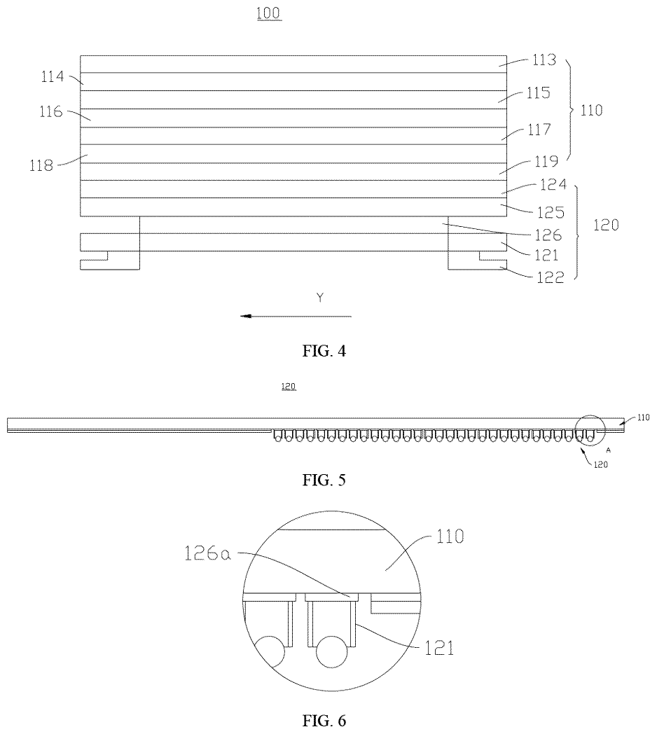

Referring to FIG. 4, in some embodiments, the supporting member 120 further includes a first adhesive layer 124, a fixing plate 125 and a second adhesive layer 126 that are sequentially stacked. The first adhesive layer 124 is adhered with the film layer group 110, and the second adhesive layer 126 is adhered with the supporting portion 121.

The fixing plate 125 is adhered with the film layer group 110 through the first adhesive layer 124, and the supporting portion 121 is fixed to the fixing plate 125 through the second adhesive layer 126. A thickness of the fixing plate 125 may be 100 um to 150 um, a tensile modulus of the fixing plate 125 may be 3 MPa to 20 MPa, and a material of the fixing plate 125 may be a steel material or a carbon fiber material. The use of the carbon fiber material may reduce a weight of the module.

In some embodiments, the thickness of the fixing plate 125 may be 105 mm, 110 mm, 115 mm, 120 mm, 125 mm or 130 mm, and the tensile modulus of the fixing plate 125 may be 4 MPa, 6 MPa, 10 MPa, 14 MPa or 18 MPa.

In some embodiments, the first adhesive layer 124 includes a substrate and a PSA (pressure sensitive adhesive). The substrate has a thickness of 25 um to 75 um and is made of PI (polyimide) material or PET (polyethylene terephthalate) material. The PSA has a thickness of 25 um to 75 um, the PSA is a low-modulus adhesive material or a medium-modulus adhesive material with a storage modulus of 20 KPa to 100 KPa, an adhesion force with the fixing plate 125 should be greater than 1000 gf/inch, and a melting point may be less than −20° C. This layer may significantly reduce a mold print of the module.

Similarly, the second adhesive layer 126 includes a substrate and a PSA. The substrate of the second adhesive layer 126 is a soft material having a thickness of 10 um to 50 um and a Young's modulus of less than 30 MPa, which may be selected from TPU (thermoplastic polyurethanes) or foam. The PSA has a thickness of 25 um to 75 um, the PSA is a low-modulus adhesive material or a medium-modulus adhesive material with a storage modulus of 20 KPa to 100 KPa, an adhesion force with the supporting portion 121 should be greater than 1000 gf/inch, and a melting point of the PSA may be less than −20° C.

In some embodiments, the thickness of the substrate of the first adhesive layer 124 may be 30 um, 35 um, 40 um, 45 um, 50 um, 60 um or 70 um, the thickness of the PSA of the first adhesive layer 124 may be 30 um, 35 um, 40 um, 45 um, 50 um, 60 um or 70 um, and the storage modulus may be 30 KPa, 40 KPa, 50 KPa, 60 KPa, 70 KPa, 80 KPa or 90 KPa. The adhesion force with the fixing plate 125 may be 1100 gf/inch, 1200 gf/inch, 1250 gf/inch, 1300 gf/inch, or 1350 gf/inch. The melting point may be −22° C., −25° C., −26°C., −29°C. or −30° C.

The thickness of the substrate of the second adhesive layer 126 may be 30 um, 35 um, 40 um, 45 um, 50 um, 60 um or 70 um, the thickness of the PSA of the second adhesive layer 126 may be 30 um, 35 um, 40 um, 45 um, 50 um, 60 um or 70 um, and the storage modulus may be 30 KPa, 40 KPa, 50 KPa, 60 KPa, 70 KPa, 80 KPa or 90 KPa. The adhesion force with the supporting portion 121 may be 1100 gf/inch, 1200 gf/inch, 1250 gf/inch, 1300 gf/inch, or 1350 gf/inch. The melting point may be −22° C., −25° C., −26°C., −29° C. or −30° C.

In some embodiments, in the width direction of the film layer group 110, a distance between an edge of a projection of the second adhesive layer 126 on the film layer group 110 and an edge of the film layer group 110 is less than 2.5 mm. Such arrangement allows the second adhesive layer 126 to be recessed inward in the width direction of the film layer group 110, thereby reducing a risk of peeling of the second adhesive layer 126.

The distance between the edge of the projection of the second adhesive layer 126 on the film layer group 110 and the edge of the film layer group 110 may be 2.4 mm, 2.3 mm, 2.2 mm, 2.1 mm or 1.8 mm.

Referring to FIG. 2 and FIG. 3, in some embodiments, the second adhesive layer 126 covers the supporting strip 121a and the gap between two adjacent supporting strips 121a. The second adhesive layer 126 may be a whole arranged between the supporting strip 121a and the fixing plate 125. The second adhesive layer 126 is further arranged in the gap between two adjacent supporting strips 121a. In this case, an area of the second adhesive layer 126 is relatively large, which may facilitate mounting and fixing of the supporting strip 121a.

It should be noted that the second adhesive layer 126 is only arranged on the supporting strip 121a, and there is no need to arrange the second adhesive layer 126 in a region of the connecting portion 121b. That is, the region of the connecting portion 121b is not connected with the film layer group 110 through the second adhesive layer 126, the fixing plate 125 and the first adhesive layer 124. The sliding portion 122 is mounted on the connecting portion 121b and is slidably connected with the housing. Such design may reduce the film layer strain at two ends of the film layer group 110 in the width direction when the sliding portion 122 slides relative to the housing, thereby improving a reliability of the entire display film layer.

The second adhesive layer 126 is only arranged on the supporting strip 121a, that is, an inward-recessed design is adopted to avoid the region where the connecting portion 121b is located. According to simulation results, a strain of the packaging layer may be reduced by 20% to 35%, and a strain of a substrate of a polarizer 117 may be reduced by 5% to 15%.

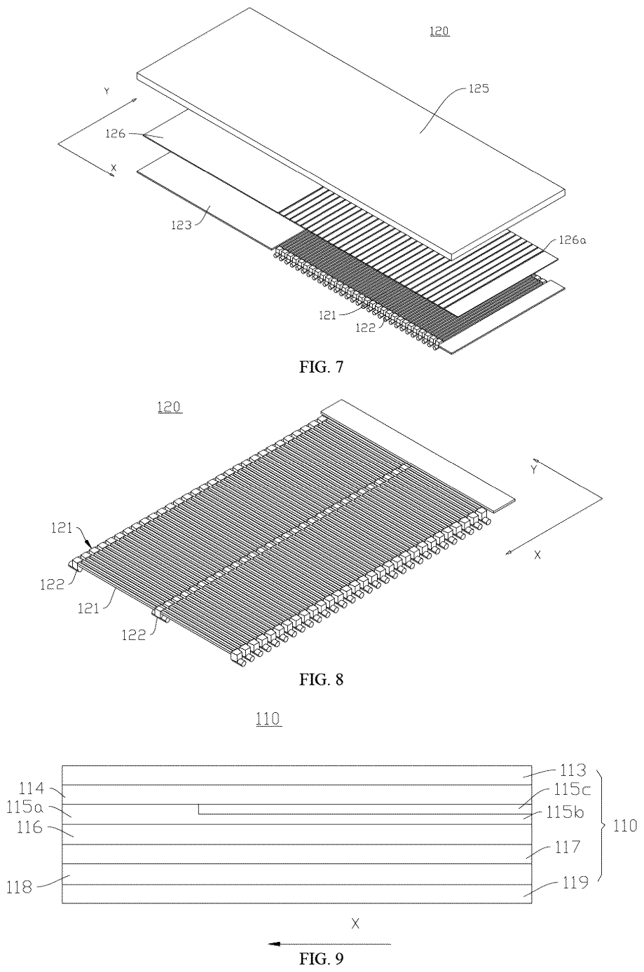

Referring to FIG. 5, FIG. 6 and FIG. 7, in some other embodiments, the second adhesive layer 126 includes a plurality of adhesive strips 126a, and each supporting strip 121a is connected with the fixing plate 125 via the adhesive strip 126a. An interrupted design is adopted for the second adhesive layer 126, and the second adhesive is designed as a plurality of independent adhesive strips 126a, which may reduce the risk of adhesive cracking of the integrated adhesive layer.

In some embodiments, in the sliding direction of the film layer group 110, the width of the adhesive strip 126a is greater than or equal to the width of the supporting strip 121a. This shows that the adhesive strip 126a completely covers the supporting strip 121a, so that a surface of the support strip facing the fixing plate 125 may be fully adhered with a supporting surface, thereby increasing an adhering area between the supporting strip 121a and the fixing plate 125, improving firmness of the supporting strip 121a and reducing the risk of peeling-off of the supporting strip 121a.

In some embodiments, in the sliding direction of the film layer group 110, a difference between the width of the adhesive strip 126a and the width of the supporting strip 121a is greater than or equal to 0.1 mm. The difference may specifically be 0.12 mm, 0.13 mm, 0.14 mm, 0.18 mm, 0.2 mm or 0.3 mm.

In some embodiments, a projection of the sliding portion 122 on the film layer group 110 falls within the film layer group 110 or is flush with the edge of the film layer group 110. That is, the sliding portion 122 is located inside the film layer group 110 and is at most flush with the edge of the film layer group 110. Such arrangement may reduce a bezel of the film layer group 110 and miniaturize a size of the entire display module.

In some embodiments, the supporting plate 123 and the supporting strip 121aprovide support for the film layer group 110, and both have a thickness of 200 um to 500 um. A connecting rib may be provided between two adjacent supporting strips 121a, or a silicone or TPU material having a modulus of 1 MPa to 6 MPa may be filled to ensure a stability of the distance between two adjacent supporting strips 121a, so as to prevent a collision between adjacent steel strips during a scrolling process.

In some embodiments, the thickness of each of the supporting plate 123 and the supporting strip 121a may be 250 um, 280 um, 300 um, 350 um, 400 um, 450 um or 480 um.

Referring to FIG. 8, in some embodiments, a plurality of supporting members 120 are provided, and the plurality of supporting members 120 are sequentially arranged in the width direction of the film layer group 110.

In the width direction of the film layer group 110, a plurality of groups of supporting members 120 may be arranged. Compared with one supporting member 120, each supporting member 120 of the plurality of groups of supporting members may have a shorter length in the width direction of the film layer group 110 and a larger contact area with the housing. The sliding portion 122 may be further arranged in a middle position of the film layer group 110, so as to support the middle position of the film layer group 110, flatten the film layer group 110, reduce the risk of arching a height in the middle of the film layer group 110, and reduce a possibility of strain in the film layer group 110.

The number of the supporting members 120 may be set according to the width of the film layer group 110 and is not specifically limited.

In some embodiments, the corresponding supporting strips 121a in two adjacent supporting members 120 may be connected to a same sliding portion 122, that is, two adjacent supporting strips 121a in the two supporting members 120 may share a sliding portion 122. For example, when two supporting members 120 are provided, two supporting strips 121a at a same width position in the width direction of the film layer group 110 form a group, the group of supporting strips 121a may only have three sliding portions 122, and the sliding portion 122 in the middle needs to connect the supporting strips 121a of the two supporting members 120 simultaneously.

In addition, two adjacent supporting members 120 may be spaced apart. In THE two adjacent supporting members 120, the sliding portions 122 are arranged adjacent to each other. Therefore, reference may be made to the distance between two adjacent sliding portions 122 for a distance between the two adjacent supporting members 120. That is, reference may be made to the second distance for the distance between the two adjacent connecting portions 121b.

Referring to FIG. 4, in some embodiments, the film layer group 110 includes a first packaging layer 113, a first connecting layer 114, a second packaging layer 115, a second connecting layer 116, a polarizer 117, a display layer 118 and a back film layer 119 stacked sequentially, and the back film layer 119 is connected with the supporting member 120.

The first packaging layer 113 may be made of a PI (polyimide) material or a PET (polyethylene terephthalate) material having a Young's modulus of approximately 4 GPa to 7 GPa and a thickness of 50 um to 90 um. In some embodiments, a surface of the first packaging layer 113 may be hardened, and a thickness of the hardened layer may be 3 um to 10 um. Such design may ensure that a strain of the first connecting layer 114 is within a safety range and no cracks occur in the hardened layer occur during the scrolling process.

The thickness of the first packaging layer 113 may be 50 um, 55 um, 60 um, 65 um, 80 um or 90 um, and the Young's modulus may be 4 GPa, 4.5 GPa, 5 GPa, 6 GPa or 7 GPa. The thickness of the hardened layer may be 3 um, 4 um, 6 um, 8 um, 9 um or 10 um.

The first connecting layer 114 is an OCA (optically clear adhesive) having a thickness of 20 um to 60 um, selected from a low-modulus adhesive material with a storage modulus less than 40 KPa and an adhesion force with the first packaging layer 113 should be greater than 1500 gf/inch. Compared with a conventional medium-modulus adhesive, such design may reduce a rebound force of the entire film layer group 110 by 20% to 40%, and reduce the strain of the first packaging layer 113 by 10% to 20%.

In some embodiments, the thickness of the first connecting layer 114 may be 25 um, 30 um, 35 um, 40 um, 45 um, 50 um or 59 um, the storage modulus may be 39 KPa, 35 KPa, 30 KPa, 25 KPa or 20 KPa, and the adhesion force with the first packaging layer 113 may be 1510 gf/inch, 1550 gf/inch, 1600 gf/inch, 1800 gf/inch or 2000 gf/inch.

The second packaging layer 115 is a reinforcement layer and may use an UTG (ultra-thin glass) material having a Young's modulus greater than 70 GPa and a thickness of 25 um to 50 um. Such design in combination with the second connecting layer 116 may significantly reduce a strain of the polarizer 117 by 20% to 50%, and reduce a risk of breakage of the substrate of the polarizer 117 in a small-radius scrolling form. Meanwhile, compared with a single-layer packaging layer design, the two-layer packaging layer design may improve a pen performance of the module by 20% to 50%.

In some embodiments, the thickness of the second packaging layer 115 may be 25 um, 30 um, 35 um, 40 um or 50 um. The Young's modulus may be 70 GPa, 80 GPa, 90 GPa, 95 GPa or 100 GPa.

The second connecting layer 116 is an OCA having a thickness of 20 um to 60 um, selected from a medium-modulus adhesive material with a storage modulus greater than 60 KPa, and an adhesion force with the second packaging layer 115 greater than 1500 gf/inch. The medium-modulus OCA may lift a neutral layer of the module, reduce a normal strain of the polarizer 117 to a safety range, and prevent the substrate of the polarizer 117 from breaking.

In some embodiments, the thickness of the second connecting layer 116 may be 25 um, 30 um, 35 um, 40 um, 50 um or 60 um, the storage modulus may be 60 KPa, 70 KPa, 80 KPa, 86 KPa or 90 KPa, and the adhesion force between the second connecting layer and the second packaging layer 115 may be 1510 gf/inch, 1550 gf/inch, 1600 gf/inch, 1800 gf/inch or 2000 gf/inch.

The polarizer 117 has a thickness of 40 um to 70 um. The substrate of the polarizer 117 may be selected from rubber, PET, TAC (tri-cellulose acetate), COP (cyclo olefin polymer), etc. The PSA should be selected from a high-modulus adhesive material with a storage modulus greater than 100 KPa to lift the neutral layer of the module and reduce the strain of the packaging layer to a safety range, preventing defects such as touch failure, abnormal display, no display, GDS (growing dark spot), etc. caused by cracks and package failure of the display module 100 in the small-radius scrolling configuration.

The back film layer 119 has a thickness of 40 um to 60 um, and may be selected from a low-modulus PI or PET material with a Young's modulus of 3 GPa to 5 GPa. According to simulation and test results, such design may provide sufficient support to ensure a yield rate of the binding process and reduce the strain of functional layers at a junction of the non-flexible region 112b and the flexible region 112a.

In some embodiments, the thickness of the back film layer 119 may be 40 um, 45 um, 48 um, 50 um, 53 um or 60 um, and the Young's modulus may be 3 GPa, 3.5 GPa, 3.8 GPa, 4 GPa or 5 GPa.

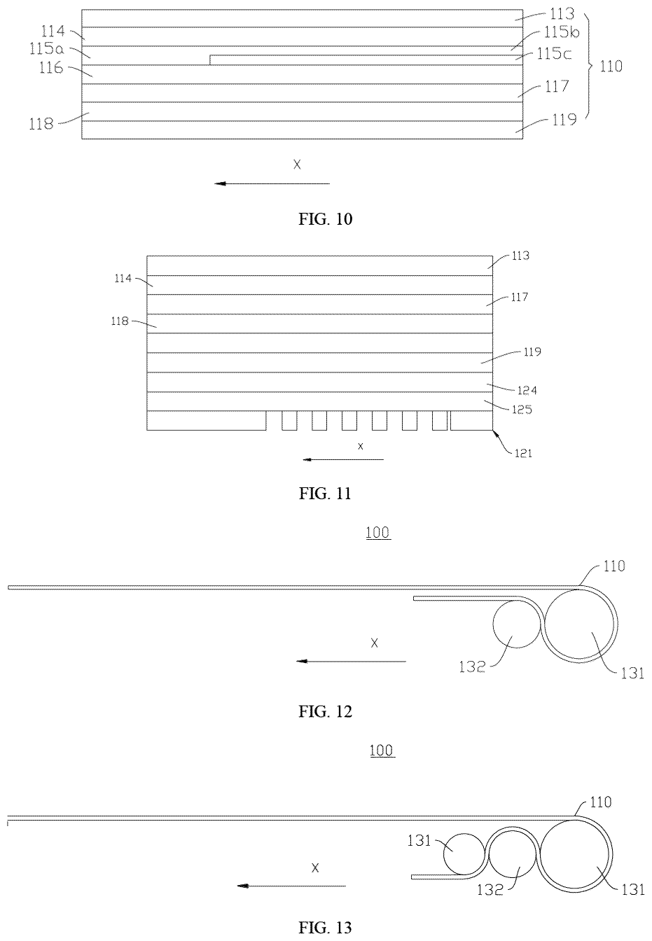

Referring to FIG. 9 and FIG. 10, in some embodiments, the second packaging layer 115 includes a first section 115a and a second section 115b connected with each other, a thickness of the first section 115a is greater than a thickness of the second section 115b, the first section 115a is arranged in the non-flexible region 112b, and the second section 115b is arranged in the flexible region 112a.

In some embodiments, the first section 115a and the second section 115b are a whole and may be integrally formed, the first section 115a and the second section 115b have different thicknesses, so that the second packaging layer 115 adopts an unequal thickness design, with a larger thickness in the non-flexible region 112b and a smaller thickness in the flexible region 112a. Since the first section 115a and the second section 115b are designed with unequal thickness, there is a certain step difference between the first section 115a and the second section 115b. The step difference may be set upward, as shown in FIG. 9, or may be set downward, as shown in FIG. 10. The step difference may be filled by an additional coating 115c, that is, the coating 115c may be filled on the second section 115b, so that the first section 115a and the second section 115b may be flush within an allowed tolerance range.

In some embodiments, the thickness of the first section 115a may be 60 um to 80 um, and the second packaging layer 115 of an different thickness may further improve a pen performance of the non-flexible region 112b. A patterned blind hole or through hole design may be used in the flexible region 112a to reduce a tensile modulus of the second section 115b, reduce the rebound force of the module, and reduce the strain of key film layers.

Referring to FIG. 11, in addition, in other embodiments, the second packaging layer 115 and the second connecting layer 116 may not be provided. If the second packaging layer 115 and the second connecting layer 116 are not provided, parameters of each film layer are as follows.

The first packaging layer 113 is selected from PI or PET material, subjected to a surface hardening treatment, having a Young's modulus of approximately 4 GPa to 7 GPa and a thickness of 70 um to 90 um. This is conducive to lifting a neutral layer of the display layer 118 to be closer to the first packaging layer 113, and reducing the risk of failure of the touch layer and the functional layers.

In some embodiments, the Young's modulus of the first packaging layer 113 is approximately 4 GPa, 4.5 GPa, 5 GPa, 5.4 GPa or 7 GPa. The thickness of the first packaging layer 113 may be 70 um, 75 um, 78 um, 80 um, 83 um or 90 um.

The first connecting layer 114 is an OCA, having a thickness of 25 um to 50 um and a storage modulus of 50 KPa to 70 KPa. Such design may effectively reduce the risk of peeling-off of the adhesive layer body here and keep strainss of other adhesive layers within a safety range.

In some embodiments, the thickness of the first connecting layer 114 may be 25 um, 30 um, 35 um, 45 um or 50 um. The storage modulus may be 50 KPa, 55 KPa, 60 KPa, 64 KPa, 68 KPa or 70 KPa.

The polarizer 117 has a thickness of 60 um to 70 um and a Young's modulus of 4 GPa to 5 GPa. The polarizer 117 may include a linear polarizing layer, a phase difference layer, a TAC film, a COP film, a pressure sensitive adhesive, etc.

In some embodiments, the thickness of the polarizer 117 may be 60 um, 62 um, 64 um, 65 um, 68 um or 70 um, and the Young's modulus may be 4 GPa, 4.1 GPa, 4.2 GPa, 4.5 GPa, 4.7 GPa or 5 GPa.

The display layer 118 has display and touch functions, and a polarizing material may also be integrated into the display layer 118. If such design is used, the polarizer 117 may be eliminated. In this case, the first connecting layer 114 should be selected from an adhesive material with a higher modulus to reduce the strains of the touch layer and the packaging layer. The storage modulus of the first connecting layer 114 varies to a range from 50 KPa to 130 KPa, and may specifically be 50 KPa, 60 KPa, 70 KPa, 90 KPa, 110 KPa or 130 KPa. In other embodiments, the display layer 118 may not have a touch function, and the touch layer may also be designed as an external layer.

The back film layer 119 has a thickness of 40 um to 60 um and may use a low-modulus PI or PET material having a Young's modulus of 3 GPa to 4 GPa. According to simulation and test results, such design may provide sufficient support to ensure the yield rate of the binding process and reduce the strain of the functional layers at the junction of the non-flexible region 112b and the flexible region 112a.

In some embodiments, the thickness of the back film layer 119 may be 40 um, 43 um, 48 um, 50 um, 55 um or 60 um, and the Young's modulus may be 3 GPa, 3.2 GPa, 3.5 GPa, 3.8 GPa or 4 GPa.

The first adhesive layer 124 is selected from a foam substrate having a thickness of 50 um to 100 um and an adhesive material having a thickness of 20 um to 30 um, a storage modulus greater than 100 KPa, and an adhesion force with the fixing plate 125 greater than 1000 gf/inch. This structure may pass a reliability test.

In some embodiments, the thickness of the foam substrate of the first adhesive layer 124 may be 50 um, 60 um, 70 um, 80 um, 90 um or 100 um, the thickness of the adhesive material may be 20 um, 22 um, 25 um, 28 um or 30 um, the storage modulus may be 110 KPa, 120 KPa, 125 KPa, 130 KPa or 140 KPa, and the adhesion force with the fixing plate 125 may be 1100 gf/inch, 1240 gf/inch, 1250 gf/inch, 1320 gf/inch or 2000 gf/inch.

The modulus of the fixing plate 125 in a tensile direction should be less than 4 MPa. Such design may reduce the risk of peeling-off of the first adhesive layer 124 and the second adhesive layer 126.

The modulus of the fixing plate 125 in the tensile direction may be 3.5 MPa, 3.4 MPa, 3.2 MPa, 3 MPa or 2.5 MPa.

The second adhesive layer 126 includes a substrate having a thickness of 20 um to 30 um, and a pressure sensitive adhesive having a thickness of 15 um to 30 um, a storage modulus greater than 100 KPa and an adhesion force with the fixing plate 125 greater than 1000 gf/inch. According to simulation and test results, such design may reduce the risk of poor peeling of the adhesive layer here.

The thickness of the substrate of the second adhesive layer 126 may be 20 um, 22 um, 26 um, 28 um, or 30 um. The storage modulus of the pressure sensitive adhesive of the second adhesive layer 126 may be 105 KPa, 110 KPa, 120 KPa, 130 KPa or 140 KPa. The adhesion force with the fixing plate 125 may be 1100 gf/inch, 1120 gf/inch, 1180 gf/inch, 1200 gf/inch or 1250 gf/inch.

Referring to FIG. 12, in some embodiments, a plurality of rotating shafts 130 are provided, and the flexible region 112a is sequentially wound around the rotating shafts 130.

A plurality of rotating shafts 130 may be provided, and the flexible region 112a may be sequentially wound around the rotating shafts 130, thereby achieving folding and unfolding of the flexible region 112a.

In some embodiments, the non-display surface of the film layer group 110 may be wound around the plurality of rotating shafts 130, or the display surface and non-display surface of the film layer group 110 may be alternately wound around two adjacent rotating shafts 130. That is, if one of two adjacent rotating shafts 130 contacts the non-display surface of the film layer group 110, the other of the two adjacent rotating shafts 130 contacts the display surface of the film layer group 110. The alternating contact with the display surface and the non-display surface allows the film layer group 110 to shift in two opposite directions, which may offset a stress generated by the two adjacent shafts 130 to a certain extent, and reduce the risk of strains on the film layer group 110.

It should be noted that a distance between the two adjacent rotating shafts 130 should be greater than the thickness of the film layer group 110.

In some embodiments, radii of the plurality of rotating shafts 130 decrease sequentially in the sliding direction of retracting the film layer group 110. That is, the closer the rotating shaft 130 is to a connection between the flexible region 112a and the non-flexible region 112b, the larger the radius of the rotating shaft, and the radius of the rotating shaft 130 into which the flexible region 112a is first drawn is the largest.

In some embodiments, if two rotating shafts 130 are provided, the rotating shafts 130 include a first rotating shaft 131 and a second rotating shaft 132 sequentially arranged in the sliding direction of retracting the film layer group 110, a radius of the first rotating shaft 131 is greater than a radius of the second rotating shaft 132, the radius of the first rotating shaft 131 is less than 3 mm, and the radius of the second rotating shaft 132 is greater than 1.5 mm.

In some embodiments, the first rotating shaft 131 serves as an outer sliding rotating shaft contacting the non-display surface, and the second rotating shaft 132 serves as an inner sliding rotating shaft contacting the display surface. It may be considered that the film layer group 110 contacts the first rotating shaft 131 in an outer curved form and contacts the second rotating shaft 132 in an inner curved form. The radius of the first rotating shaft 131 being less than 3 mm may make a scrolling radius of the entire display module less than 3 mm. The radius of the second rotating shaft 132 being greater than 1.5 mm may make an inner curvature radius of the film layer group 110 less than 1.5 mm, therefore reducing the risk of failure of the film layer group 110.

Referring to FIG. 13, if three rotating shafts 130 are provided, the rotating shafts 130 include a first rotating shaft 131, a second rotating shaft 132 and a third rotating shaft 133 sequentially arranged in the sliding direction of retracting the film layer group 110. A radius of the first rotating shaft 131 is greater than a radius of the second rotating shaft 132, and the radius of the second rotating shaft 132 is greater than a radius of the third rotating shaft 133. The radius of the first rotating shaft 131 is less than 2.5 mm, and the radius of the second rotating shaft 132 is greater than 1.5 mm.

Similarly, the first rotating shaft 131 serves as an outer sliding rotating shaft contacting the non-display surface, the second rotating shaft 132 serves as an inner sliding rotating shaft contacting the display surface, and the third rotating shaft 133 serves as an outer sliding rotating shaft contacting the non-display surface, so that a sufficient gap is left between the display surface and the non-display surface of the film layer group 110 to place structural parts and electronic parts of a whole machine.

In summary, in the display module 100 provided by the embodiments of the present disclosure, the sliding portion 122 is slidably connected with the housing, that is, the supporting portion 121 may be slidably connected with the housing through the sliding portion 122, and the supporting portion 121 is arranged on the non-display surface of the flexible region 112a. During the sliding process of the entire film layer group 110, the supporting portion 121 and the sliding portion 122 may cooperate to provide a certain support for the film layer group 110, reducing the stress generated during contact of the film layer group 110 with the rotating shaft 130, thereby reducing the stress-strain on the film layer group 110, reducing the occurrence of breakage of the film layer group 110 during the sliding process, and thus improving the service life of the entire display module 100.

In the descriptions of the specification, the descriptions referring to terms “an embodiment”, “some embodiments”, “example”, “specific example”, or “some examples” indicate that the specific features, structures, materials or characteristics described in conjunction with the embodiment or example are included in at least one embodiment or example of the present disclosure. In the specification, the illustrative expressions of the above terms do not necessarily refer to a same embodiment or example. Furthermore, the specific features, structures, materials, or characteristics described may be combined in any suitable manner in any one or more embodiments or examples. Additionally, those skilled in the art may combine and incorporate different embodiments or examples described in the specification.

In addition, the technical solutions of various embodiments may be combined with each another on the basis that such combination may be implemented by those of ordinary skill in the art. When the combination of technical solutions is mutually contradictory or may not be implemented, it should be deemed that such combination of technical solutions does not exist and is not within the scope of protection of the present disclosure.

Although the embodiments of the present disclosure have been shown and described, it will be understood by those skilled in the art that various changes, modifications, substitutions and variations may be made to these embodiments without departing from the principles and spirit of the present disclosure, and the scope of the present disclosure is defined by the claims and their equivalents.

1. A display module, comprising:
a film layer group comprising a flexible region and a non-flexible region connected with the flexible region;
a supporting member comprising a supporting portion and a sliding portion connected with the supporting portion, wherein the supporting portion is at least arranged in the flexible region, and the sliding portion is slidably connected with a housing; and
a rotating shaft, wherein the flexible region is wound around the rotating shaft, such that at least a part of the flexible region overlaps with the non-flexible region,
wherein the supporting member is arranged between the film layer group and the rotating shaft.

2. The display module according to claim 1, wherein,
the supporting portion comprises a plurality of supporting strips and a plurality of connecting portions, in a sliding direction of the film layer group, the plurality of supporting strips are spaced apart in the flexible region, and a connecting portion of the plurality of connecting portions connects two adjacent supporting strips; and
a plurality of sliding portions are provided, and the sliding portions are mounted on the connecting portions.

3. The display module according to claim 2, wherein in the sliding direction of the film layer group, a distance between two adjacent supporting strips of the plurality of supporting strips is a first distance, a distance between two adjacent connecting portions of the plurality of connecting portions is a second distance, and the second distance is greater than the first distance.

4. The display module according to claim 2, wherein in the sliding direction of the film layer group, a width of a supporting strip of the plurality of supporting strips is a first width, a width of the connecting portion is a second width, and the second width is greater than the first width.

5. The display module according to claim 2, wherein in the sliding direction of the film layer group, a distance between two adjacent supporting strips of the plurality of supporting strips is a first distance greater than 0.5 mm and less than 1 mm, and a width of a supporting strip of the plurality of supporting strips is a first width greater than 0.5 mm and less than 1 mm.

6. The display module according to claim 2, wherein in the sliding direction of the film layer group, a width of the connecting portion is a second width, a distance between two adjacent connecting portions of the plurality of connecting portions is a second distance, and a sum of the second width and the second distance is greater than 2 mm.

7. The display module according to claim 2, wherein the supporting member further comprises a first adhesive layer, a fixing plate, and a second adhesive layer sequentially stacked, the first adhesive layer is adhered with the film layer group, and the second adhesive layer is adhered with the supporting portion.

8. The display module according to claim 7, wherein in a width direction of the film layer group, a distance between an edge of a projection of the second adhesive layer on the film layer group and an edge of the film layer group is less than 2.5 mm.

9. The display module according to claim 7, wherein the second adhesive layer covers the supporting strips and a gap between the two adjacent supporting strips.

10. The display module according to claim 7, wherein the second adhesive layer comprises a plurality of adhesive strips, and each of the plurality of supporting strips is connected with the flexible region via an adhesive strip of the plurality of adhesive strips.

11. The display module according to claim 10, wherein in the sliding direction of the film layer group, a width of the adhesive strip is greater than or equal to a width of the supporting strip.

12. The display module according to claim 10, wherein in the sliding direction of the film layer group, a difference value between a width of the adhesive strip and a width of the supporting strip is greater than or equal to 0.1 mm.

13. The display module according to claim 7, wherein a thickness of the first adhesive layer is 25 um to 75 um, and a thickness of the second adhesive layer is 25 um to 75 um.

14. The display module according to claim 1, wherein a projection of the sliding portion on the film layer group is located within the film layer group or flush with an edge of the film layer group.

15. The display module according to claim 1, wherein a plurality of supporting members are provided, and the plurality of supporting members are sequentially arranged in a width direction of the film layer group.

16. The display module according to claim 1, wherein the film layer group comprises a first packaging layer, a first connecting layer, a polarizer, a display layer, and a back film layer sequentially stacked, and the back film layer is connected with the supporting member.

17. The display module according to claim 16, wherein,
the film layer group further comprises a second packaging layer and a second connecting layer, the second packaging layer is arranged between the first connecting layer and the second connecting layer, and the second connecting layer is arranged between the second packaging layer and the polarizer;
the second packaging layer comprises a first section and a second section connected with each other, a thickness of the first section is greater than a thickness of the second section, the first section is arranged in the non-flexible region, and the second section is arranged in the flexible region; and
a thickness of the first packaging layer is 50 um to 90 um, a thickness of the first connecting layer is 20 um to 60 um, a thickness of the second packaging layer is 25 um to 50 um, a thickness of the second connecting layer is 20 um to 60 um, a thickness of the polarizer is 40 um to 70 um, and a thickness of the back film laver is 40 um to 60 um.

18. (canceled)

19. The display module according to claim 1, wherein a plurality of rotating shafts are provided, the flexible region is sequentially wound around the plurality of rotating shafts, and different sides of the film layer group respectively contact two adjacent rotating shafts.

20. The display module according to claim 19, wherein.
in a sliding direction of retracting the film layer group, radii of the plurality of rotating shafts decrease sequentially;
the rotating shaft comprises a first rotating shaft and a second rotating shaft sequentially arranged in the sliding direction of retracting the film layer group, a radius of the first rotating shaft is greater than a radius of the second rotating shaft, the radius of the first rotating shaft is less than 3 mm, and the radius of the second rotating shaft is greater than 1.5 mm; or the rotating shaft comprises a first rotating shaft, a second rotating shaft, and a third rotating shaft sequentially arranged in the sliding direction of retracting the film layer group, a radius of the first rotating shaft is greater than a radius of the second rotating shaft, the radius of the second rotating shaft is greater than a radius of the third rotating shaft, the radius of the first rotating shaft is less than 2.5 mum, and the radius of the second rotating shaft is greater than 1.5 mm.

21. (canceled)

22. (canceled)

23. A display apparatus, comprising the display module according to claim 1.
